(19) United States
(12) Patent Application Publication
(10) Pub. No.: US 2013/0176669 A1
(43) Pub. Date: Jul. 11, 2013

(54) TERMINAL HOLDING DEVICE

(71) Applicants: Hideaki Takahashi, Ageo (JP); Yusuke Imasaka, Sayama (JP); Kenji Nakamura, Tokorozawa (JP); Yoshiaki Tsuchida, Ota (JP)

(72) Inventors: Hideaki Takahashi, Ageo (JP); Yusuke Imasaka, Sayama (JP); Kenji Nakamura, Tokorozawa (JP); Yoshiaki Tsuchida, Ota (JP)

(73) Assignee: PIONEER CORPORATION, Kanagawa (JP)

(21) Appl. No.: 13/822,496

(22) PCT Filed: Sep. 16, 2010
(86) PCT No.: PCT/JP2010/066068

§ 371 Date: Mar. 12, 2013

(51) Int. Cl. H05K 7/00

(52) U.S. Cl. CPC H05K 7/00
USPC 361/679.01

(57) ABSTRACT

The terminal holding device is attached to an installation surface such as a dashboard of a vehicle by an attaching unit. A supporting unit has one end connected to the attaching unit in such a manner that the angle is adjustable, and the other end connected to the holding unit which holds the terminal device. A sensor substrate for holding a sensor is mounted on the holding unit so as to be perpendicular to the display surface of the terminal device held by the holding unit. Normally, in order to easily view the display unit of the terminal device, a user will install the terminal device such that the display surface thereof is nearly perpendicular to the ground. Because the sensor substrate is mounted on the holding unit so as to be perpendicular to the display surface of the terminal device, the sensor substrate is mounted horizontally to the ground.

### TECHNICAL FIELD

The present invention relates to a terminal holding device used to install a terminal device in a movable body.

### BACKGROUND TECHNIQUE

Recently, a portable type navigation device is widely used. Patent Document 1 discloses an example of installing a portable type navigation device in a vehicle by using a cradle.

On the other hand, recently, a portable type terminal device such as a high-function portable telephone called “smartphone” is installed and used in a movable body such as a vehicle. Applications similar to the navigation device are proposed for a smartphone, and a smartphone can be installed in a vehicle to be used as a navigation device. Generally, a smartphone have a GPS function, but does not have a sensor such as a gyro sensor. Therefore, there is proposed such a technique that a gyro sensor is provided in a cradle and the output of the gyro sensor is supplied to a smartphone, thereby achieving a highly accurate navigation function.

Generally, detection accuracy of the gyro sensor becomes low if it is not installed level with the ground. In a case where the cradle is equipped with the gyro sensor, since a user installs the cradle at free position and angle, the cradle is not necessarily installed in such a manner that the gyro sensor becomes horizontal. If the cradle is installed in a such manner that the gyro sensor is inclined, the gyro sensor cannot detect angular velocity and acceleration accurately.

Patent Documents 2 and 3 disclose measures to install a gyro sensor horizontally. However, in both cases, a user needs to install the device in consideration of a state of the gyro sensor.

### PRIOR ART DOCUMENTS

### Patent Documents

Patent Document 1: Japanese Patent Application Laid-open under No. 2010-86215
Patent Document 2: Japanese Patent Application Laid-open under No. 2007-205759
Patent Document 3: WO1999/002943

### SUMMARY OF INVENTION

### Problem to be Solved by the Invention

The above is one example of the problem to be solved by the present invention. It is an object of the present invention to provide a terminal holding device for which no special setting by a user is needed and by which a sensor can be held in a horizontal state even if the user freely installs it.

### Means for Solving the Problem

According the present invention, there is provided a terminal holding device which holds a terminal device and which is installed in a movable body, including: an attaching unit which attaches the terminal holding device to an installation surface of the movable body; a supporting unit, one end of which is adjustably connected to the attaching unit; a holding unit which is connected to the other end of the supporting unit and which holds the terminal device; and a sensor substrate which is mounted on the holding unit so as to be perpendicular to a display surface of the terminal device held by the holding unit.

According to the present invention, there is provided a terminal holding device which holds a terminal device and which is installed in a movable body, including: an attaching unit which attaches the terminal holding device to an installation surface of the movable body; a supporting unit, one end of which is adjustably connected to the attaching unit; a holding unit which is connected to the other end of the supporting unit and which holds the terminal device; and a sensor substrate which is mounted on the holding unit so as to be perpendicular to a display surface of the terminal device held by the holding unit, wherein the sensor substrate is mounted on a position inclined, by an angle within a range of a tolerable inclination angle of a sensor, from a position perpendicular to the display surface.

According to the present invention, there is provided a terminal holding device which holds a terminal device provided with a display surface and which is installed in a movable body, including: an attaching unit which attaches the terminal holding device to an installation surface of the movable body; a supporting unit, one end of which is adjustably connected to the attaching unit; a holding unit which is connected to the other end of the supporting unit and which holds the terminal device; and a sensor substrate which is mounted on the holding unit.

### BRIEF DESCRIPTION OF THE DRAWINGS

FIGS. 1A to 1C are a front view, a side view and a rear view of a terminal holding device according to an embodiment of the invention.

FIGS. 2A and 2B are a front view and a rear perspective view of the terminal holding device shown in FIGS. 1A to 1C.

FIGS. 3A to 3D are diagrams illustrating rotated states of a terminal holder.

FIGS. 4A to 4E are diagrams for explaining advantage of making the terminal holder rotatable by every 90 degrees.

FIGS. 5A to 5C are diagrams illustrating relationship between inclination of the terminal holder and inclination of a sensor substrate.

FIGS. 6A to 6C are diagrams illustrating relationship between inclination of the terminal holder and inclination of the sensor substrate.

FIG. 7 is a side view illustrating a configuration of a terminal holding device according to a modified example.

### MODE TO EXERCISE THE INVENTION

According to a preferred mode of the invention, a terminal holding device which holds a terminal device and which is installed in a movable body, includes: an attaching unit which attaches the terminal holding device to an installation surface of the movable body; a supporting unit, one end of which is adjustably connected to the attaching unit; a holding unit which is connected to the other end of the supporting unit and which holds the terminal device; and a sensor substrate which is mounted on the holding unit so as to be perpendicular to a display surface of the terminal device held by the holding unit.

The above terminal holding device is installed in a movable body such as a vehicle, and holds the terminal device. The terminal holding device is attached to an installation surface such as a dashboard of the vehicle by an attaching unit which functions as a base at the time of the attachment. To the attaching unit, one end of the supporting unit is connected in such a manner that its attaching angle is adjustable. To the other end of the supporting unit, the holding unit which holds the terminal device is connected. On the holding unit, the sensor substrate for holding a sensor such as a gyro sensor is mounted in such a manner that the sensor substrate becomes perpendicular to the display surface of the terminal device held by the holding unit.

Normally, a user installs the terminal device in such a manner that the display surface of the terminal device is easy to see, i.e., its display surface becomes substantially perpendicular to the ground. Since the sensor substrate is mounted on the holding unit so as to be perpendicular to the display surface of the terminal device, the sensor substrate is mounted horizontally to the ground. Therefore, the user can install the terminal holding device in such a state that the sensor substrate is horizontal, without the need of considering the sensor.

According to one mode of the above terminal holding device, the holding unit includes: an axis unit connected to the other end of the supporting unit; and a fixing unit which is rotatable around the axis unit serving as an axis and which fixes the terminal device, and the sensor substrate is mounted on the axis unit. In this mode, the axis unit serving as a rotation axis is provided on the other end of the supporting unit, and the sensor substrate is mounted on the axis unit. Also, the fixing unit holds the terminal device, and rotates around the axis unit serving as an axis. Therefore, the user can rotate the terminal device with keeping the sensor substrate in the horizontal state.

According to another mode of the above terminal holding device, the fixing unit is fixable at every 90 degrees rotated positions with respect to the axis unit. In this mode, the fixing unit can fix the terminal device only at every 90 degrees. Therefore, at the time of installing the terminal holding device on an inclined installation surface, the user adjusts the angle of the attaching unit and/or the supporting unit so that the supporting unit does not become the inclined state. Or the user installs the terminal holding device to a horizontal installation surface so that the holding unit does not become the inclined state. Thus, the sensor held by the holding unit is kept in the horizontal state. Namely, by forming the fixing unit fixable only at every 90 degrees, the user is guided to install the terminal holding device in such a state that the sensor substrate becomes horizontal.

According to still another mode of the above terminal holding device, the sensor substrate is mounted on the holding unit so as to be perpendicular to either one of a longitudinal direction or a lateral direction of the display surface, when the fixing unit is fixed to the axis unit. Thus, it is ensured that the sensor substrate is arranged horizontally.

According to still another mode of the above terminal holding device, the holding unit is adjustably connected to the supporting unit, and its adjustable range is set in accordance with a tolerable inclination angle of the sensor substrate. Thus, when the user finely adjusts the inclination of the terminal device by changing the angle of the holding unit with respect to the supporting unit, it can be prevented that the inclination of the sensor substrate exceeds the tolerable inclination angle.

According to another mode of the present invention, a terminal holding device which holds a terminal device and which is installed in a movable body, includes: an attaching unit which attaches the terminal holding device to an installation surface of the movable body; a supporting unit, one end of which is adjustably connected to the attaching unit; a holding unit which is connected to the other end of the supporting unit and which holds the terminal device; and a sensor substrate which is mounted on the holding unit so as to be perpendicular to a display surface of the terminal device held by the holding unit, wherein the sensor substrate is mounted on a position inclined, by an angle within a range of a tolerable inclination angle of a sensor, from a position perpendicular to the display surface.

The above terminal holding device is installed in a movable body such as a vehicle, and holds the terminal device. The terminal holding device is attached to an installation surface such as a dashboard of the vehicle by an attaching unit which functions as a base at the time of the attachment. To the attaching unit, one end of the supporting unit is connected in such a manner that its attaching angle is adjustable. To the other end of the supporting unit, the holding unit which holds the terminal device is connected. On the holding unit, the sensor substrate for holding a sensor such as a gyro sensor is mounted in such a manner that the sensor substrate is inclined within the tolerable inclination angle with respect to the position perpendicular to the display surface of the terminal device held by the holding unit. Thus, when the user installs the terminal holding device in the movable body such that the display surface of the terminal device is directed slightly upwardly, the sensor is mounted substantially horizontally to the ground.

According to still another mode of the present invention, the terminal holding device which holds a terminal device provided with a display surface and which is installed in a movable body, includes: an attaching unit which attaches the terminal holding device to an installation surface of the movable body; a supporting unit, one end of which is adjustably connected to the attaching unit; a holding unit which is connected to the other end of the supporting unit and which holds the terminal device; and a sensor substrate which is mounted on the holding unit.

The above terminal holding device is installed on a movable body such as a vehicle, and holds the terminal device. The terminal holding device is attached to an installation surface such as a dashboard of the vehicle by an attaching unit which functions as a base at the time of the attachment. To the attaching unit, one end of the supporting unit is connected in such a manner that its attaching angle is adjustable. To the other end of the supporting unit, the holding unit which holds the terminal device is connected. The holding unit holds the sensor substrate for holding a sensor such as a gyro sensor. Therefore, by installing the terminal holding device, the sensor substrate is mounted.

According to one mode of the above terminal holding device, the holding unit includes a contact surface which contacts a casing surface parallel with the display surface of the terminal device, and the sensor substrate is mounted so as to be perpendicular to the contact surface. Thereby, when the user installs the terminal holding device on the installation surface in such a manner that the display surface of the terminal device is perpendicular to the ground, the sensor substrate is constantly kept horizontal.

In a preferred example, the sensor substrate detects at least one of angular velocity and acceleration horizontally around the movable body.

### Embodiment

The preferred embodiment of the present invention will now be described below with reference to the attached drawings.

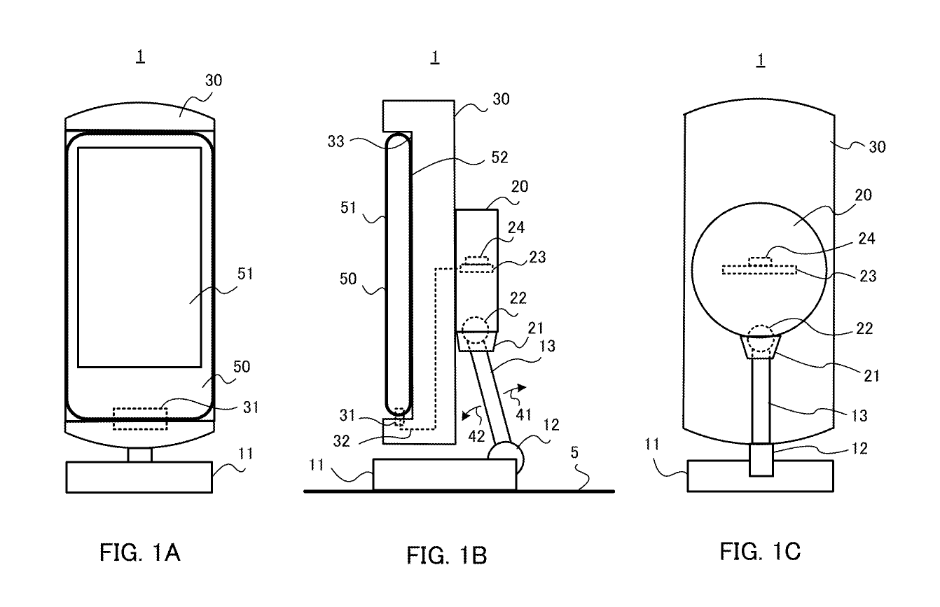

FIGS. 1A to 1C illustrate a terminal holding device 1 according to an embodiment of the present invention. The terminal holding device 1 functions as a so-called cradle, to which a terminal device 50 such as a smartphone is attached.

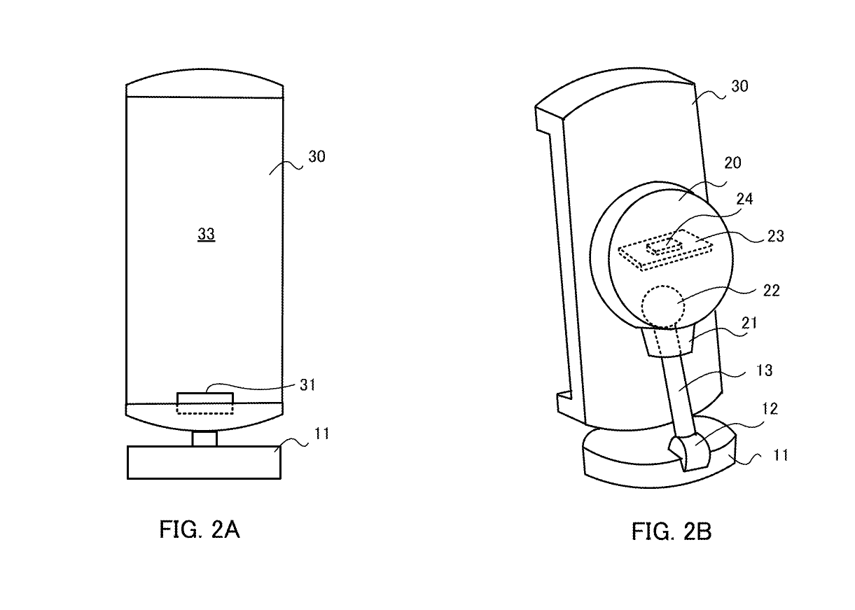

FIGS. 1A to 1C illustrate the terminal holding device 1 in a state that it is holding the terminal device 50. Specifically, FIG. 1A is a front view of the terminal holding device 1, FIG. 1B is a side view of the terminal holding device 1, and FIG. 1C is a rear view of the terminal holding device 1. FIG. 2A is a front view of the terminal holding device 1 in a state that it is not holding the terminal device 50. FIG. 2B is a perspective view of the terminal holding device 1 observed from its rear side, in a state that it is not holding the terminal device 50.

As illustrated, the terminal holding device 1 includes a base 11, a hinge 12, an arm 13, a substrate holder 20 and a terminal holder 30.

The base 11 functions as a base used when the terminal holding device 1 is attached to a movable body such as a vehicle.

For example, the base 11 is provided with a sucker or an adhesive tape at its underside, and the base 11 is fixed to an installation surface 5 such as a dashboard of the vehicle by the adhesive tape.

The hinge 12 is fixed to the arm 13, and is attached to the base 11 in a manner rotatable with respect to the base 11. By the rotation of the hinge 12, the arm 13 swings in a front-rear direction of the terminal device 50, i.e., in a direction of the arrows 41 and 42 in FIG. 1B. Namely, by rotating the arm 13 via the hinge 12 with respect to the base 11 fixed to the installation surface 5 of the vehicle, it is possible to adjust the installation angle of the substrate holder 20 and the terminal holder 30 with respect to the installation surface 5.

The substrate holder 20 is a holder which holds a substrate for a gyro sensor. Specifically, the substrate holder 20 includes a cover 21, a ball link 22, a sensor substrate 23 and a sensor 24.

The ball link 22 is attached to an upper end of the arm 13, and holds the substrate holder 20 at an arbitrary angle with respect to the arm 13. The cover 21 is provided at a lower end of the substrate holder 20, and has a function of restricting the rotation of the substrate holder 20 with respect to the arm 13, the detail of which will be described later.

The sensor substrate 23 is provided inside of the substrate holder 20, and the sensor substrate 23 is provided with the sensor 24. A preferred example of the sensor 24 is a gyro sensor which detects at least one of angular velocity and acceleration horizontally around the movable body.

The terminal holder 30 is a holder which holds the terminal device 50. The terminal holder 30 includes a connector 31 and a wiring 32. The connector 31 is provided at the bottom of the front surface, i.e., the surface on which the terminal device 50 is set, and is connected to the connector of the terminal device 50 when the terminal device 50 is set in the terminal holder 30. The connector 31 is electrically connected to the sensor substrate 23 via the wiring 32. Therefore, the detection signal of the sensor 24 is supplied to the terminal device 50 via the sensor substrate 23, the wiring 32 and the connector 31.

The terminal device 50 includes a display surface 51, which is a front side of the body of the terminal device 50 and includes a display unit, and a rear surface 52 which is a rear side of the body of the terminal device 50. Normally, the terminal device 50 is formed in a rectangular flat-plate shape, and the display surface 51 and the rear surface 52 are substantially parallel with each other.

The terminal holder 30 has a contact surface 33 at its front side. When the terminal device 50 is mounted on the terminal holder 30, the contact surface 33 contacts and supports the rear surface 52 of the terminal device 50. In the example shown in FIGS. 1A and 1B, the contact surface 33 of the terminal holder 30 is formed such that its entire surface contacts the rear surface 52 of the terminal device 50. Instead, it is possible to employ such a configuration that one or plural parts of the contact surface 33 is formed to be partly protruding, and only the protruding parts contact the rear surface 52 of the terminal device 50.

In the above-described configuration, the base 11 constitutes an attaching unit of the invention, and the hinge 12, the arm 13 and the ball link 22 constitute a supporting unit of the invention. The substrate holder 20 and the terminal holder 30 constitute a holding unit of the invention. The substrate holder 20 constitutes an axis unit, and the terminal holder 30 constitutes a fixing unit. Further, the rear surface 52 of the terminal device 50 constitutes a casing surface of the invention.

Next, the rotation function of the terminal holder 30 with respect to the substrate holder 20 will be described. The terminal holder 30 holding the terminal device 50 is rotatable, by the unit of 90 degrees, with respect to the substrate holder 20. Namely, when the state shown in FIG. 1A is defined as the rotation angle 0 degree, the terminal holder 30 can be fixed in four states being rotated by 0 degree, 90 degrees, 180 degrees and 270 degrees in a clockwise or counterclockwise direction. The reason why it can be fixed by the unit of 90 degrees is that a user normally uses the terminal device 50 in such a state that the display unit is arranged vertically or laterally, when the user sees the display unit. As described above, the terminal device 50 normally has a rectangular flat-plate shape. “Arranging vertically” means such an arrangement that the longitudinal direction of the display unit is vertical, and “arranging laterally” means such an arrangement that the longitudinal direction of the display unit is lateral.

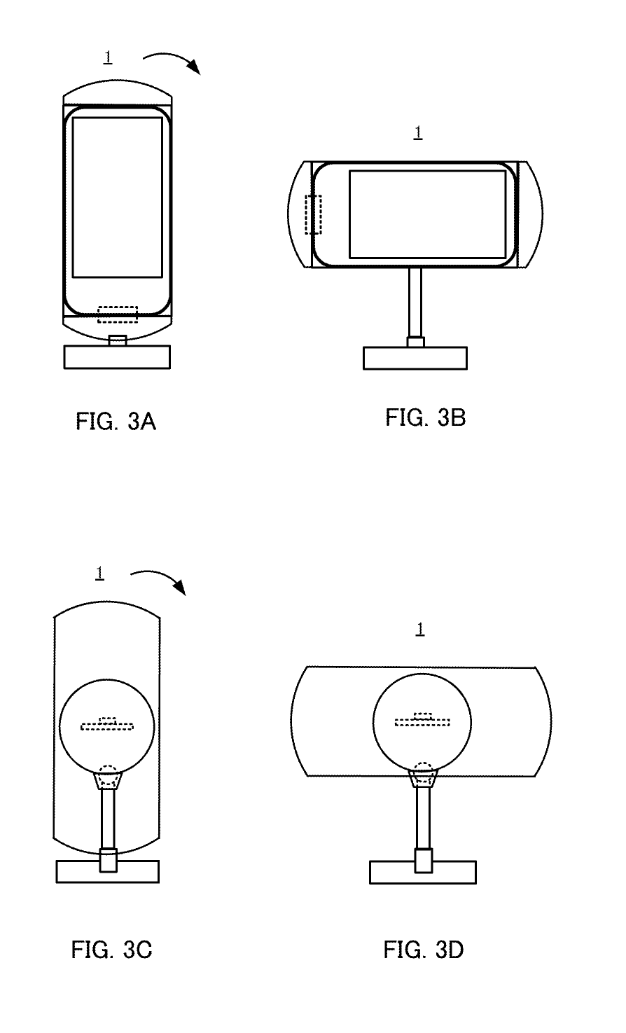

FIGS. 3A to 3D illustrate the states in which the terminal holder 30 is rotated. When the terminal holding device 1 is observed from the front side, rotating the terminal holder 30 by 90 degrees in the direction of the arrow from the state of FIG. 3A results in the state of FIG. 3B. When the terminal holding device is observed from the rear side, rotating the terminal holder 30 in the direction of the arrow from the state of FIG. 3C results in the state of FIG. 3D.

Structurally, by providing a rotational axis (not shown) at a substantial center of the substrate holder 20 and fixing the terminal holder 30 to the rotational axis, the terminal holder 30 becomes rotatable with respect to the substrate holder 20. Also, by providing pairs of concavity-convexity or recess-protrusion engage with each other at the positions of every 90-degree rotation angles, to the surface where the substrate holder 20 and the terminal holder 30 abut with each other, the terminal holder 30 can be fixed at the positions of every 90-degree rotation angles. The above-described structure is merely an example, and other structure may be employed as long as the terminal holder 30 can be fixed to the substrate holder 20 at every 90-degree rotation angles.

Next, the setting angle of the sensor substrate 23 will be described. As illustrated in FIG. 1B, in this embodiment, the sensor substrate 23 is fixed to the substrate holder 20 so as to be perpendicular to the display surface 51 of the terminal device 50. As described above, the terminal device 50 is normally formed in a rectangular flat-plate shape, and the display surface 51 and the rear surface 52 are substantially parallel with each other. Also, as described above, the rear surface 52 of the terminal device 50 and the contact surface 33 of the terminal holder 30 are substantially parallel with each other. Therefore, the sensor substrate 23 is normally mounted on to the substrate holder 20 so as to be perpendicular to the display surface 51 and the rear surface 52 of the terminal device 50 as well as the contact surface 33 of the terminal holder 30. Further, the sensor substrate 23 is mounted on the substrate holder 20 so as to be perpendicular to the longitudinal direction or the lateral direction of the display surface 51, when the terminal holder 30 is fixed in such a state that it is rotated by one of the above-mentioned four angles of 90-degree difference.

By mounting the sensor substrate 23 on the substrate holder 20 in this manner, the sensor substrate 23 is mounted horizontally, i.e., in a state being substantially parallel with the ground, in whatever state the user attaches the terminal holding device 1 to the installation surface 5 of the vehicle. This is because, the user normally installs the terminal holding device 1 in such a manner that the display surface 51 of the terminal device 50 becomes substantially perpendicular to the ground. Normally, the user sits on the seat of the vehicle in a posture looking the advancing direction and keeping his or her upper half of body substantially perpendicular to the ground. Therefore, the user installs the terminal holding device 1 to the installation surface 5 of the vehicle such that the display surface 51 substantially directly confronts the user, i.e., the display surface 51 becomes perpendicular to the ground. Even if the installation surface 5 is an inclined surface, the user must adjust the angle by the rotation angle adjusting function by the hinge 12 and the ball link 22 of the terminal holding device such that the display surface 51 of the terminal device 50 becomes substantially perpendicular to the ground. Therefore, at whatever position the terminal holding device 1 is installed, the sensor substrate 23 is always arranged horizontally, i.e., in parallel with the ground. As a result, the sensor 24 such as a gyro sensor is always set horizontally, thereby enabling accurate detection.

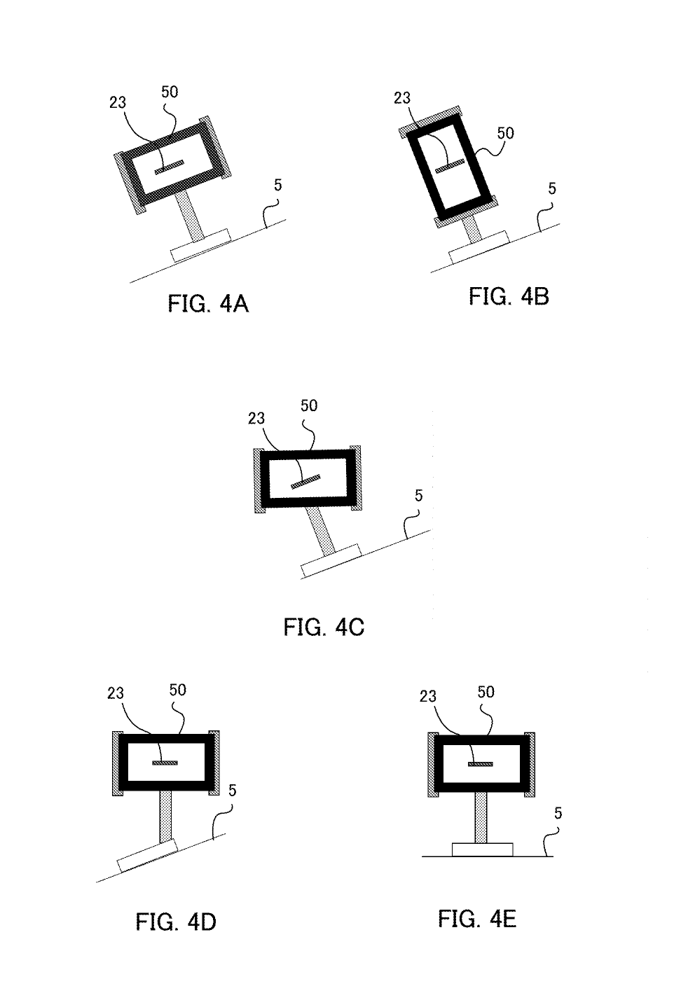

With reference to FIGS. 4A to 4E, the setting angle of the sensor substrate 23 will be further described. In this embodiment, the terminal holder 30 can be fixed to the substrate holder 20 only at every 90-degree rotation angle. Therefore, it is not possible to fix the terminal holder 30 at such a rotation angle that the display unit is arranged laterally or longitudinally as shown in FIG. 4C, when the terminal holding device 1 is attached to the inclined installation surface 5 of the vehicle. If the terminal holder 30 is rotated by the unit of 90-degrees, the display unit of the terminal device 50 becomes inclined as shown in FIGS. 4A and 4B, and the sensor substrate 23 is also inclined. Therefore, the user uses the hinge 12 to adjust the angle such that the display unit of the terminal device 50 is not inclined as shown in FIG. 4D. As a result, naturally the sensor substrate 23 becomes horizontal. Or the user avoids the inclined installation surface 5 and chooses a flat installation surface 5 as shown in FIG. 4E, and hence the sensor substrate 23 is set horizontally. In this way, according to this embodiment, the user does not have to consider the inclination of the sensor substrate 23 and the sensor substrate 23 is held in the horizontal state, as long as the user installs the terminal device 50 in an easy-to-see state, i.e., in such a state that the display surface is substantially perpendicular to the ground and is not inclined.

Next, description will be given of such a function that the rotation of the substrate holder 20 by the ball link 22 is regulated by the cover 21 of the substrate holder 20. In this embodiment, in addition to that the sensor substrate 23 is held horizontally as described above, the rotation of the substrate holder 20 is regulated by the cover 21 to further ensure that the sensor substrate 23 is held in a nearly horizontal state.

A sensor such as a gyro sensor is preferably used in a horizontal state, and its tolerable angle of inclination (hereinafter referred to as “tolerable inclination angle”) is determined. Namely, the sensor can perform accurate detection when it is set within the tolerable inclination angle, even if it is not completely in a horizontal state. Therefore, in this embodiment, when the terminal holding device 1 is attached to the installation surface 5, the cover 21 regulates the rotation of the substrate holder 20 such that the angle of the sensor substrate 23 does not exceed the tolerable inclination angle.

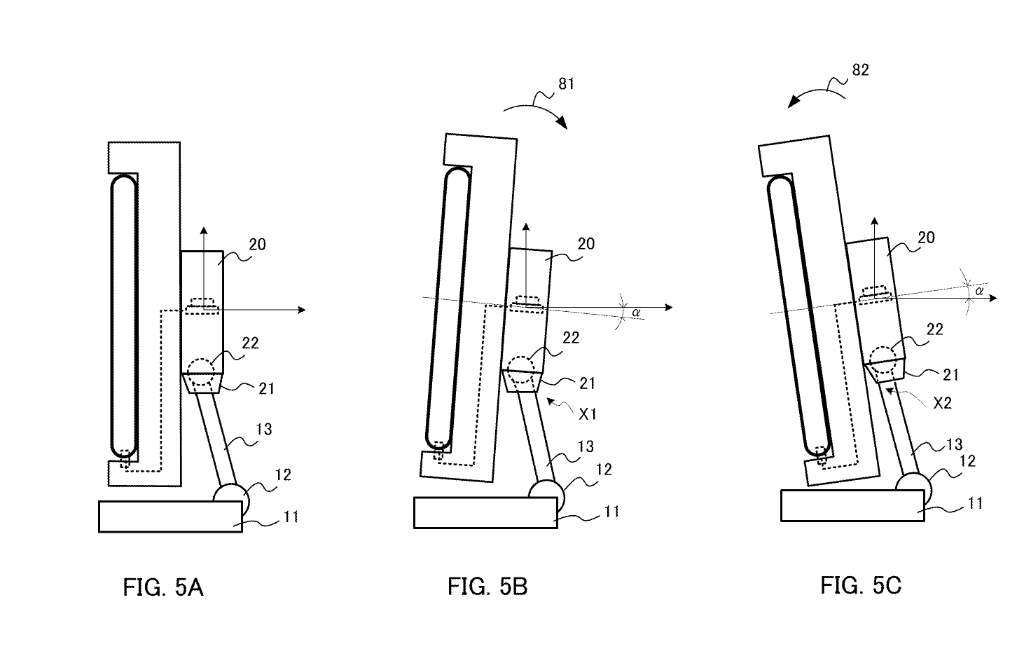

FIGS. 5A to 5C illustrate the states of rotating the substrate holder 20 and the terminal holder 30 in the front and rear direction by using the ball link 22. In the following description, the substrate holder 20 and the terminal holder 30 integrally rotated is referred to as “holding unit” for convenience of explanation. The tolerable inclination angle of the sensor 24 is expressed as “α”.

FIG. 5A illustrates a state wherein the rotation of the ball link 22 is regulated such that the terminal device 50 becomes substantially perpendicular to the ground. In this case, the sensor substrate 23 is held in a horizontal state. Also, in this case, the upper end of the arm 13 does not contact the edge of the lower end of the cover 21, and the cover 21 does not regulate the rotation of the holding unit.

FIG. 5B illustrates a state wherein the holding unit is rotated in the direction of the arrow 81 by using the ball link 22. When the holding unit is rotated in the direction of the arrow 81, the sensor substrate 23 is also inclined with respect to the horizontal direction accordingly. However, when the inclination angle of the sensor substrate 23 reaches the tolerable inclination angle α, the arm 13 contacts the edge of the lower end of the cover 21, as shown by the arrow X1, to regulate the rotation of the holding unit. Namely, the holding unit cannot rotate in the direction of the arrow 81 any further. Thus, the sensor substrate 23 is prevented from being inclined larger than the tolerable inclination angle α with respect to the horizontal direction.

FIG. 5C illustrates a state wherein the holding unit is rotated in the direction of the arrow 82, i.e., in the direction opposite to FIG. 5A, by using the ball link 22. Also in this case, when the inclination angle of the sensor substrate 23 reaches the tolerable inclination angle α, the edge of the lower end of the cover 21 contacts the arm 13 as shown by the arrow X2, and further rotation is prevented. Thus, the sensor substrate 23 is prevented from being inclined larger than the tolerable inclination angle α with respect to the horizontal direction.

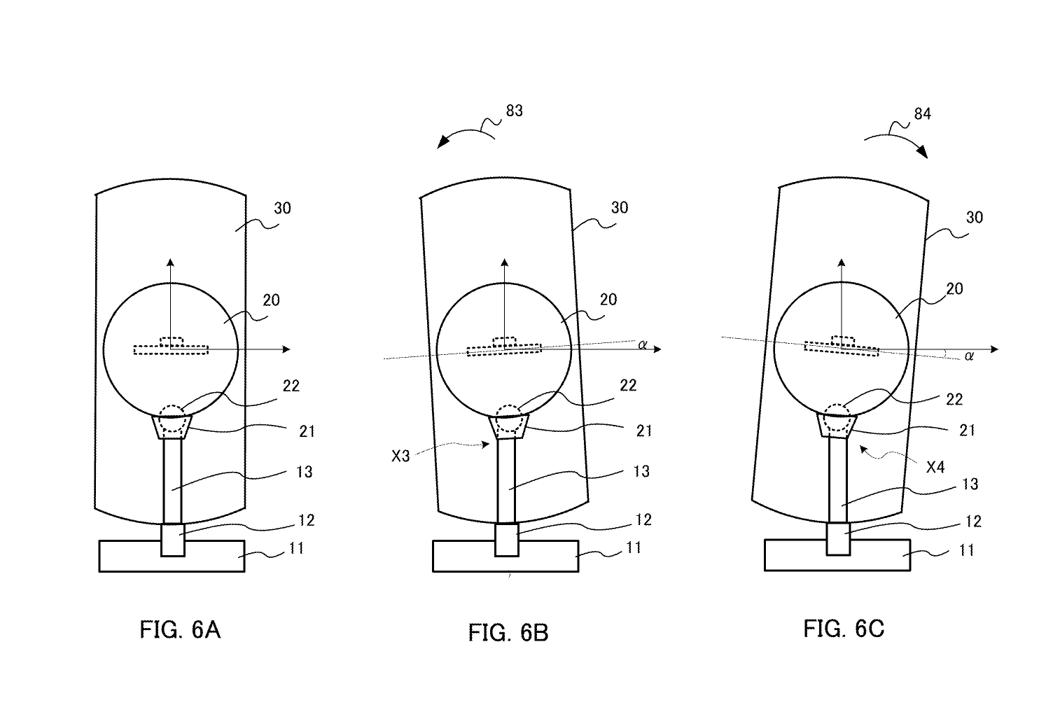

FIGS. 6A to 6C illustrate the states of rotating the holding unit in the left and right direction by using the ball link 22. In FIG. 6A, the sensor substrate 23 is held in a horizontal state. In this case, the edge of the lower end of the cover 21 does not contact the arm 13, and the cover 21 does not regulate the rotation of the holding unit.

FIG. 6B illustrates a state wherein the holding unit is rotated in the direction of the arrow 83 by using the ball link 22. When the holding unit is rotated in the direction of the arrow 83, the sensor substrate 23 is also inclined with respect to the horizontal direction accordingly. However, when the inclination angle of the sensor substrate 23 reaches the tolerable inclination angle α, the arm 13 contacts the edge of the lower end of the cover 21 to regulate the rotation of the holding unit. Namely, the holding unit cannot be rotated in the direction of the arrow 83 any further. Thus, the sensor substrate 23 is prevented from being inclined larger than the tolerable inclination angle α with respect to the horizontal direction.

FIG. 6C illustrates a state wherein the holding unit is rotated in the direction of the arrow 84, i.e., in the direction opposite to FIG. 6A, by using the ball link 22. Also in this case, when the inclination angle of the substrate 23 reaches the tolerable inclination angle α, the edge of the lower end of the cover 21 contacts the arm 13 to prevent further rotation. Thus, the sensor substrate 23 is prevented from being inclined larger than the tolerable inclination angle α with respect to the horizontal direction.

As described above, in this embodiment, the cover 21 regulates the rotation of the holding unit by using the ball link 22, and therefore the sensor substrate 23 is prevented from being inclined larger than the tolerable inclination angle. While the above example employs such a structure that the cover 21 has a taper shape and its diameter at the lower end is smaller than that of the upper end, this is merely an example. The rotation of the holding unit by using the ball link 22 may be regulated by other structure. For example, the rotation larger than the tolerable inclination angle may be prevented by adjusting the diameter at the lower end of the cover 21 and the diameter of the arm 13, without making the shape of the cover 21 tapered.

As described above, according to the terminal holding device 1 of this embodiment, since the sensor substrate 23 is mounted so as to be perpendicular to the display surface 51 of the terminal device 50, the sensor substrate 23 is held substantially horizontally only if the user attaches the terminal holding device 1 to the installation surface 5 of the vehicle in a normal, easy-to-see condition. Therefore, the user can mount the terminal holding device 1 without considering the inclination angle of the sensor substrate 23.

Further, since the terminal holding device 1 has a structure that the rotation of the holding unit by using the ball link 22 is regulated such that the inclination angle of the sensor substrate 23 does not exceed the tolerable inclination angle, the sensor substrate 23 is not inclined larger than the tolerable inclination angle even if the user finely adjusts the angle of the substrate holder 20 by using the rotation function of the ball link 22.

### Modified Examples

While the above-described embodiment is configured such that the terminal holder 30 can be rotated around the substrate holder 20 serving as the axis, the present invention is not limited to this example. For example, in a case of a terminal device that is arranged only in one of the longitudinal and lateral direction, the terminal holder 30 may be configured non-rotatable with respect to the substrate holder 20.

While the terminal holder 30 is configured to be fixable in the states rotated by 0 degree, 90 degrees, 180 degrees and 270 degrees with respect to the substrate holder 20 in the above embodiment, the present invention is not limited to this example.

For example, the terminal holder 30 may be configured to be fixable in two states rotated by 0 degree and 90 degrees with respect to the substrate holder 20. Namely, the terminal device 50 may be arranged in two state, i.e., longitudinally or laterally.

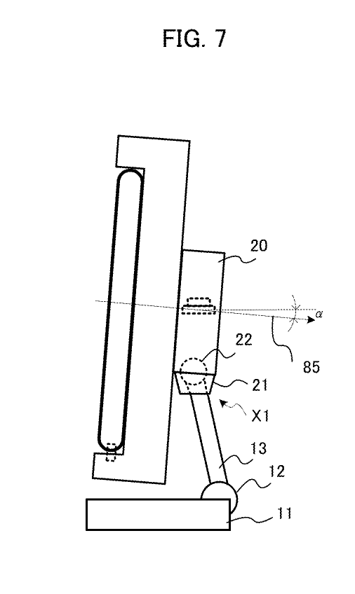

In the above embodiment, the sensor substrate 23 is mounted on the substrate holder 20 so as to be perpendicular to the display surface 51 of the terminal device 50. However, the sensor substrate 23 may be, not completely perpendicular, but inclined within the tolerable inclination angle of the sensor substrate 23. FIG. 7 illustrates a side view of the terminal holding device according to this modified example. In the example of FIG. 7, the arrow 85 indicates the direction perpendicular to the display surface 51 of the terminal device 50, and the sensor substrate 23 is mounted on the substrate holder 20 in a state being inclined by the tolerable inclination angle α with respect to the direction of the arrow 85. Namely, the sensor substrate 23 is mounted on the substrate holder 20 to have an angle (90-α) degrees with respect to the display surface 51 of the terminal device 50. Therefore, the sensor substrate 23 becomes substantially parallel with the ground when the terminal holding device 1 is installed in the vehicle such that the display surface 51 of the terminal device 50 is directed slightly upwardly.

### DESCRIPTION OF REFERENCE NUMBERS

1 Terminal Holding Device
11 Base
12 Hinge
13 Arm
20 Substrate Holder
21 Cover
22 Ball Link
23 Sensor Substrate
24 Sensor
30 Terminal Holder
50 Terminal Device

1. A terminal holding device which holds a terminal device and which is installed in a movable body, comprising:
an attaching unit which attaches the terminal holding device to an installation surface of the movable body;
a supporting unit, one end of which is adjustably connected to the attaching unit;
a holding unit which is connected to the other end of the supporting unit and which holds the terminal device; and
a sensor substrate which is mounted on the holding unit so as to be perpendicular to a display surface of the terminal device held by the holding unit.

2. The terminal holding device according to claim 1,
wherein the holding unit comprises: an axis unit connected to the other end of the supporting unit; and a fixing unit which is rotatable around the axis unit serving as an axis and which fixes the terminal device, and
wherein the sensor substrate is mounted on the axis unit.

3. The terminal holding device according to claim 2, wherein the fixing unit is fixable at every 90 degree rotated positions with respect to the axis unit.

4. The terminal holding device according to claim 3,
wherein the sensor substrate is mounted on the holding unit so as to be perpendicular to either one of a longitudinal direction or a lateral direction of the display surface, when the fixing unit is fixed to the axis unit.

5. The terminal holding device according to claim 1, wherein the holding unit is adjustably connected to the supporting unit, and wherein its adjustable range is set in accordance with a tolerable inclination angle of the sensor substrate.

6. A terminal holding device which holds a terminal device and which is installed in a movable body, comprising:
an attaching unit which attaches the terminal holding device to an installation surface of the movable body;
a supporting unit, one end of which is adjustably connected to the attaching unit;
a holding unit which is connected to the other end of the supporting unit and which holds the terminal device; and
a sensor substrate which is mounted on the holding unit so as to be perpendicular to a display surface of the terminal device held by the holding unit,
wherein the sensor substrate is mounted on a position inclined, by an angle within a range of a tolerable inclination angle of a sensor, from a position perpendicular to the display surface.

7. A terminal holding device which holds a terminal device provided with a display surface and which is installed in a movable body, comprising:
an attaching unit which attaches the terminal holding device to an installation surface of the movable body;
a supporting unit, one end of which is adjustably connected to the attaching unit;
a holding unit which is connected to the other end of the supporting unit and which holds the terminal device; and
a sensor substrate which is mounted on the holding unit,
wherein the holding unit comprises a contact surface which contacts a casing surface parallel with the display surface of the terminal device, and
wherein the sensor substrate is mounted so as to be perpendicular to the contact surface.

8. (canceled)

9. The terminal holding device according to claim 1, wherein the sensor substrate detects at least one of angular velocity and acceleration horizontally around the movable body.

10. The terminal holding device according to claim 2, wherein the holding unit is adjustably connected to the supporting unit, and wherein its adjustable range is set in accordance with a tolerable inclination angle of the sensor substrate.

11. The terminal holding device according to claim 3, wherein the holding unit is adjustably connected to the supporting unit, and wherein its adjustable range is set in accordance with a tolerable inclination angle of the sensor substrate.

12. The terminal holding device according to claim 4, wherein the holding unit is adjustably connected to the supporting unit, and wherein its adjustable range is set in accordance with a tolerable inclination angle of the sensor substrate.

13. The terminal holding device according to claim 2, wherein the sensor substrate detects at least one of angular velocity and acceleration horizontally around the movable body.

14. The terminal holding device according to claim 3, wherein the sensor substrate detects at least one of angular velocity and acceleration horizontally around the movable body.

15. The terminal holding device according to claim 4, wherein the sensor substrate detects at least one of angular velocity and acceleration horizontally around the movable body.

16. The terminal holding device according to claim 5, wherein the sensor substrate detects at least one of angular velocity and acceleration horizontally around the movable body.

17. The terminal holding device according to claim 6, wherein the sensor substrate detects at least one of angular velocity and acceleration horizontally around the movable body.

18. The terminal holding device according to claim 7, wherein the sensor substrate detects at least one of angular velocity and acceleration horizontally around the movable body.

19. The terminal holding device according to claim 8, wherein the sensor substrate detects at least one of angular velocity and acceleration horizontally around the movable body.
